(19) United States
(12) Patent Application Publication
(10) Pub. No.: US 2014/0186982 A1
(43) Pub. Date: Jul. 3, 2014

(54) ORGANIC LIGHT EMITTING DIODE DISPLAY AND MANUFACTURING METHOD THEREOF

(71) Applicant: Samsung Display Co., Ltd., Yongin-City (KR)

(72) Inventor: Kuen-Dong HA, Yongin-City (KR)

(21) Appl. No.: 14/199,450

(22) Filed: Mar. 6, 2014

Related U.S. Application Data
(62) Division of application No. 12/954,972, filed on Nov. 29, 2010.

(30) Foreign Application Priority Data
May 14, 2010 (KR) 10-2010-0045575

(51) Int. Cl. H01L 51/56

(52) U.S. Cl. CPC H01L 51/56
USPC 438/34

(57) ABSTRACT

An organic light emitting diode (OLED) display includes a display substrate, an encapsulation substrate facing the display substrate; a soft sealant disposed between the display substrate and the encapsulation substrate and adhering the display substrate and the encapsulation substrate to each other; and a brittle sealant connecting a side of the display substrate and a side of the encapsulation substrate. Therefore, the organic light emitting diode (OLED) display does not generate cracks on the attachment surface of the soft sealant and display substrate and encapsulation substrate because the soft sealant has a high fracture toughness even though a stress concentration phenomenon occurs on the attachment surface of the soft sealant, the display substrate and encapsulation substrate Therefore, it is possible to prevent the display substrate and encapsulation substrate from being easily broken because of the external impact or deformation thereof.

### CROSS-REFERENCE TO RELATED APPLICATION

This application claims the benefit of Korean Patent Application No. 10-2010-0045575, filed May 14, 2010, in the Korean Intellectual Property Office, the disclosure of which is incorporated herein by reference.

### BACKGROUND

1. Field

The described technology relates generally to an organic light emitting diode (OLED) display and a manufacturing method thereof.

2. Description of the Related Art

In general, an organic light emitting diode (OLED) display includes a display substrate, an encapsulated substrate, and a sealant. The display substrate has an organic light emitting diode. The encapsulation substrate is disposed so as to face the display substrate, thereby protecting the organic light emitting diode of the display substrate. The sealant adheres the display substrate and the encapsulation substrate and seals them.

The organic light emitting diode (OLED) display has a problem that it is easily deteriorated in the case of when the moisture permeates the organic emission layer. In order to prevent this, the organic light emitting diode (OLED) display is sealed by using an organic substrate as the encapsulation substrate and using a frit as the sealant. However, even though the organic light emitting diode (OLED) display is sealed by using the frit, there is a limit in complete prevention of the moisture permeation. In addition, in the case of when the display substrate and the encapsulation substrate are separated from each other because of an external impact or deformation thereof, a stress concentration phenomenon occurs on the attachment surface of the frit and the display substrate and encapsulation substrate. Thus, cracks occur on the attachment surface thereof since the frit is brittle, such that the cracks are diffused over the entire display substrate.

In addition, in the case of when the frit sealant is used, in order to prevent the occurrence of cracks, an epoxy sealant that is a buffer agent may be used. However, in this case, the permeation problem is continuously generated.

The above information disclosed in this Background section is only for enhancement of understanding of the background of the described technology and therefore it may contain information that does not form the prior art that is already known in this country to a person of ordinary skill in the art.

### SUMMARY

The described technology has been made in an effort to provide an organic light emitting diode (OLED) display having advantages of improving impact resistance and durability, and a manufacturing method thereof.

An exemplary embodiment provides the organic light emitting diode (OLED) display includes: a display substrate; an encapsulation substrate facing the display substrate; a soft sealant disposed between the display substrate and the encapsulation substrate and adhering the display substrate and the encapsulation substrate to each other; and a brittle sealant connecting a side of the display substrate and a side of the encapsulation substrate.

According to an aspect of the invention, the brittle sealant fills a space between the display substrate and the encapsulation substrate, and the soft sealant and the brittle sealant are separated from each other at a predetermined interval.

According to an aspect of the invention, the soft sealant includes any one of epoxy, acrylate, urethaneacrylate, cyanoacrylate, and the brittle sealant includes a frit material.

According to an aspect of the invention, the encapsulation substrate is any one of glass, metal or plastic.

Another embodiment provides a method for manufacturing an organic light emitting diode (OLED) display includes forming a soft sealant around a display substrate; contacting a horizontal surface of an encapsulation substrate with a portion of the soft sealant at an adhesion angle relative to a horizontal surface of the display substrate; applying a pressure to a portion of the encapsulation substrate so that the horizontal surface of the encapsulation substrate is parallel to the horizontal surface of the display substrate and so that the display substrate and the encapsulation substrate adhere to each other.

According to an aspect of the invention, the method further includes forming a brittle sealant that connects a side of the display substrate and a side of the encapsulation substrate to each other after the display substrate and the encapsulation substrate are cohered with each other.

According to an aspect of the invention, the brittle sealant fills a space between the display substrate and the encapsulation substrate.

According to aspects of the present invention, the organic light emitting diode display does not generate cracks on the attachment surface of the soft sealant, the display substrate and the encapsulation substrate because the soft sealant has a high fracture toughness. Even though a stress concentration phenomenon occurs on the attachment surface of the soft sealant, the display substrate and the encapsulation substrate cracks are prevented by adhering the display substrate and the encapsulation substrate by using the soft sealant. Therefore, it is possible to prevent the display substrate and encapsulation substrate from being easily broken because of external impact or deformation thereof.

According to an aspect of the invention, since it is possible to prevent permeation of the moisture by encapsulating a side space of the display substrate and encapsulation substrate by using the brittle sealant, it is possible to improve impact resistance and moisture permeability.

According to an aspect of the invention, the encapsulation substrate is contacted to a portion of the soft sealant so that the horizontal surface of the encapsulation substrate forms an adhesion angle relative to the horizontal surface of the display substrate to form an inclination state. Also, pressure is applied to a portion of the encapsulation substrate so that the horizontal surface of the encapsulation substrate is parallel to the horizontal surface of the display substrate. Thus, even though the display substrate and the encapsulation substrate are separated by the external impact, the display substrate and the encapsulation substrate can be separated while cracks do not occur on the attachment surface of the soft sealant, the display substrate and the encapsulation substrate until the maximum adhesion angle.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a top plan view of an organic light emitting diode (OLED) display according to an exemplary embodiment;

FIG. 2 is a cross-sectional view that is taken along the line II-II of FIG. 1;

FIG. 3 is a layout view that expands a portion of the display area of FIG. 1;

FIG. 4 is a cross-sectional view that is taken along the line IV-IV of FIG. 3;

FIG. 5 is a view that illustrates a step for forming a soft sealant on a display substrate in the manufacturing method of the organic light emitting diode (OLED) display according to an exemplary embodiment;

FIG. 6 is a view that illustrates a step for pressing a portion of the encapsulation substrate in the manufacturing method of the organic light emitting diode (OLED) display according to an exemplary embodiment; and

FIG. 7 is a view that illustrates a step for curing the soft sealant in the manufacturing method of the organic light emitting diode (OLED) display according to an exemplary embodiment.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

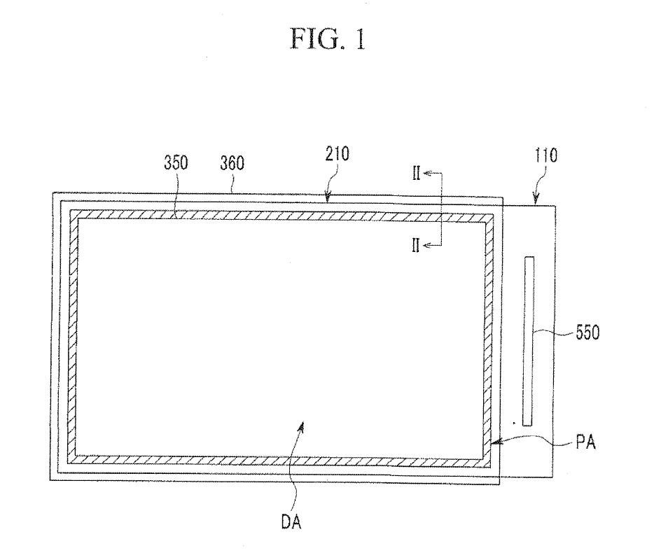

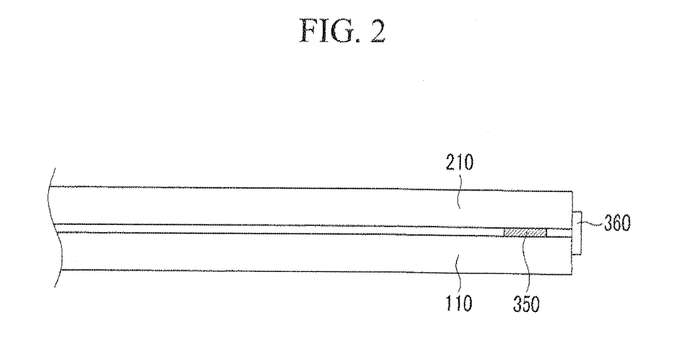

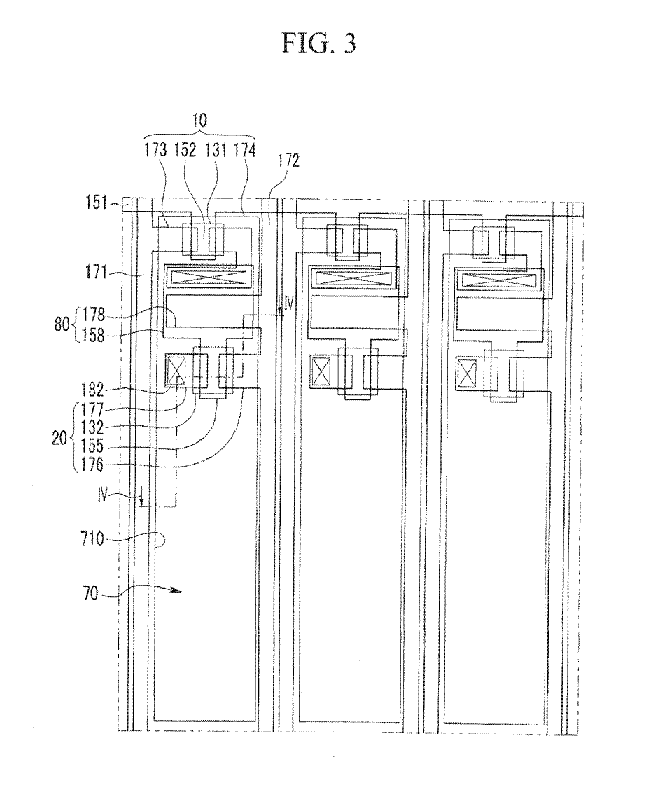

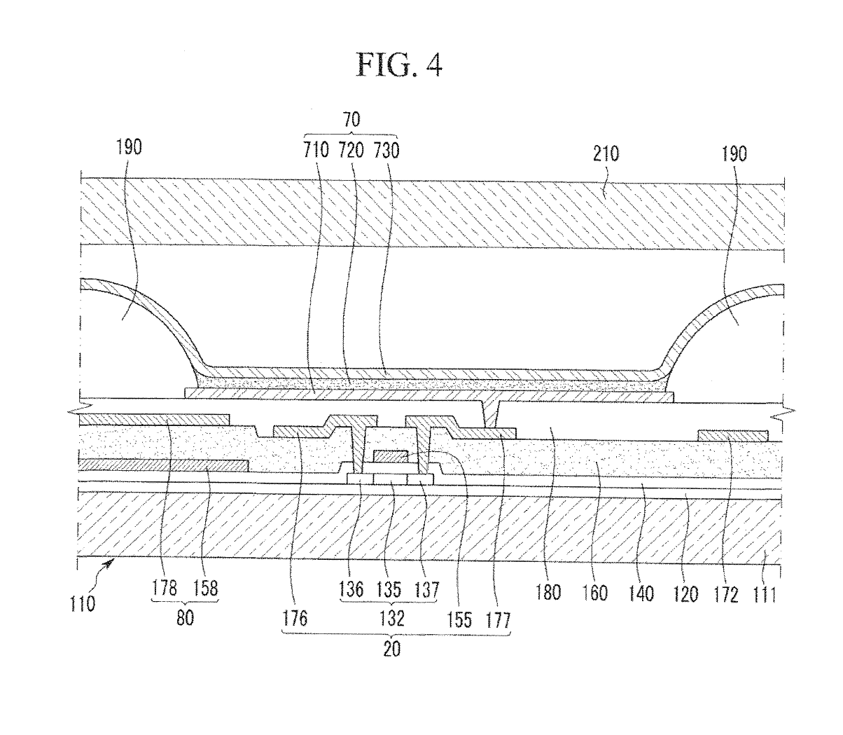

Hereinafter, an organic light emitting diode (OLED) display according to an exemplary embodiment will be described in detail with reference to FIG. 1 to FIG. 2. FIG. 1 is a top plan view of an organic light emitting diode (OLED) display according to an exemplary embodiment, FIG. 2 is a cross-sectional view that is taken along the line II-II of FIG. 1, FIG. 3 is a layout view that expands a portion of the display area of FIG. 1, and FIG. 4 is a cross-sectional view that is taken along the line IV-IV of FIG. 3.

As shown in FIG. 1 and FIG. 2, the organic light emitting diode (OLED) display includes a display substrate 110, an encapsulation substrate 210 that covers the display substrate 110, a soft sealant 350 that is disposed between the display substrate 110 and the encapsulation substrate 210, and a brittle sealant 360 that connects a side of the display substrate 110 and a side of the encapsulation substrate 210. In addition, a driving circuit chip 550 is shown mounted on an edge of a side of the display substrate 110 that is not covered by the encapsulation substrate 210, although the invention is not limited thereto.

The display substrate 110 includes a display area (DA) on which at least one organic light emitting element is formed and a peripheral area (PA) that is an outside of the display area (DA). In addition, in the display area (DA), a plurality of pixels are formed, thus forming an image.

Referring to FIGS. 3 and 4, an internal structure of the organic light emitting diode (OLED) display will be described on the basis of the pixel on the display area (DA). As shown in FIG. 3, the display substrate 110 includes a switching thin film transistor 10, a driving thin film transistor 20, a capacitor element 80 and an organic light emitting diode (OLED) 70 for each single pixel. In addition, the display substrate 110 further includes a gate line 151 that is disposed along a predetermined direction. A data line 171 and a common electric power line 172 cross the gate line 151 but are insulated from the gate line 151. One pixel may be defined by the gate line 151, data line 171 and common electric power line 172 as the boundary thereof, but the invention is not limited thereto.

The organic light emitting diode 70 includes a first electrode 710, an organic emission layer 720 that is formed on the first electrode 710, and a second electrode 730 that is formed on the organic emission layer 720. Herein, the first electrode 710 is an anode (+) that is a hole injection electrode, and the second electrode 730 is a cathode (−) that is an electron injection electrode. Holes and electrons are injected into the organic emission layer 720 from the first electrode 710 and the second electrode 730. When an exciton in which the injected holes are cohered with an electron falls from the excited state to the bottom state, light emitting is accomplished.

The capacitor element 80 includes the first capacitor plate 158 and the second capacitor plate 178 that are separated by an interlayer insulating layer 160. The interlayer insulating layer 160 is a dielectric material. The capacitor capacitance is determined by the charge that is accumulated in the capacitor element 80 and the voltage between both capacitor plates 158 and 178.

The switching thin film transistor 10 includes the switching semiconductor layer 131, a switching gate electrode 152, a switching source electrode 173 and a switching drain electrode 174. The driving thin film transistor 20 includes a driving semiconductor layer 132, a driving gate electrode 155, a driving source electrode 176 and a driving drain electrode 177.

The switching thin film transistor 10 is a switching element that selects the pixel that emits light. The switching gate electrode 152 is connected to the gate line 151. The switching source electrode 173 is connected to the data line 171. The switching drain electrode 174 is separated from the switching source electrode 173 and is connected to the first capacitor plate 158.

The driving thin film transistor 20 applies a driving power for emitting light of the organic emission layer 720 of the organic light emitting diode 70 to the first electrode 710 in the selected pixel. The driving gate electrode 155 is connected to the first capacitor plate 158. The driving source electrode 176 and the second capacitor plate 178 are each connected to the common power line 172. The driving drain electrode 177 is connected to the first electrode 710 of the organic light emitting diode 70 through the electrode contact hole 182.

By the above structure, the switching thin film transistor 10 is operated by the gate voltage that is applied to the gate line 151 and transfers the data voltage that is applied to the data line 171 to the driving thin film transistor 20. The voltage that corresponds to a difference in the common voltage that is applied from the common power line 172 to the driving thin film transistor 20 and the data voltage that is transferred from the switching thin film transistor 10. The voltage is stored in the capacitor element 80. The current that corresponds to the voltage that is stored in the capacitor element 80 flows through the driving thin film transistor 20 to the organic light emitting diode 70 to allow the organic light emitting diode 70 to emit light.

Referring to FIG. 4, a structure of an organic light emitting diode (OLED) display according to the first exemplary embodiment will be described in detail according to the layering order. The first substrate member 111 forms the display substrate 110. The first substrate member 111 is formed of an insulating substrate that is made of glass, quartz, ceramic, plastic and the like. However, the present invention is not limited thereto. Accordingly, the first substrate member 111 may be formed of a metal substrate that is made of stainless steel and the like.

The buffer layer 120 is formed on the first substrate member 111. The buffer layer 120 prevents impure elements from being permeated and planarizes the surface. The buffer layer 120 may be formed of various materials that can perform these functions. For example, the buffer layer 120 may use any one of silicon nitride (SiNx) film, silicon oxide SiO₂ film, and silicon nitroxide (SiOxNy) film. However, the buffer layer 120 is not the necessary constitution, and may be omitted according to the kind and the process condition of the first substrate member 111.

The driving semiconductor layer 132 is formed on the buffer layer 120. The driving semiconductor layer 132 is formed of the polysilicon film. In addition, the driving semiconductor layer 132 includes a channel region 135 in which an impurity is not doped, and a source region 136 and a drain region 137 that are p+ doped at both ends of the channel region 135. As shown, the doped ion material is the p type impurity such as boron (B) and B₂H₆ is mainly used. This impurity varies according to the kind of the thin film transistor. However, the invention is not limited thereto.

A gate insulating layer 140 is on the driving semiconductor layer 132, a gate insulating layer 140 is formed of silicon nitride (SiNx) or silicon oxide SiO₂ is formed. On the gate insulating layer 140, the gate wire that includes the driving gate electrode 155 is formed. In addition, the gate wire further includes a gate line 151, the first capacitor plate 158 and the other wire. Further, the driving gate electrode 155 is formed so as to overlap at least a portion of the driving semiconductor layer 132, particularly the channel region 135.

The interlayer insulating layer 160 is on the gate insulating layer 140. The interlayer insulating layer 160 also covers the driving gate electrode 155. The gate insulating layer 140 and the interlayer insulating layer 160 have through-holes that expose the source region 136 and drain region 137 of the driving semiconductor layer 132. The interlayer insulating layer 160, like the gate insulating layer 140, can be made of a ceramic-based material such as silicon nitride (SiNx) or silicon oxide SiO₂.

On the interlayer insulating layer 160 is a data wire that includes the driving source electrode 176 and driving drain electrode 177. In addition, the data wire further includes a data line 171, the common power line 172, the second capacitor plate 178 and the other wire. In addition, the driving source electrode 176 and driving drain electrode 177 are connected to the source region 136 and drain region 137 of the driving semiconductor layer 132 through the through-holes that are formed on the interlayer insulating layer 160 and gate insulating layer 140.

As described above, the driving thin film transistor 20 includes the driving semiconductor layer 132, driving gate electrode 155, driving source electrode 176 and driving drain electrode 177. The constitution of the driving thin film transistor 20 is not limited the above examples, but may be variously modified with the known constitution that can be easily performed by those who are skilled in the art.

A planarization layer 180 is on the interlayer insulating layer 160. The planarization layer 180 covers the data wires 172, 176, 177, and 178. The planarization layer 180 removes a step and performs planarization in order to increase the luminous efficiency of the organic light emitting diode 70 to be formed thereon. In addition, the planarization layer 180 has an electrode contact hole 182 that exposes a portion of the drain electrode 177. The planarization layer 180 may be made of at least one of material of polyacrylates resin, epoxy resin, phenolic resin, polyamides resin, polyimides rein, unsaturated polyesters resin, polyphenylenethers resin, polyphenylenesulfides resin and benzocyclobutene (BCB).

In addition, the shown embodiment according to the present invention is not limited to the above structures, and it is understood that any one of the planarization layer 180 and the interlayer insulating layer 160 may be omitted.

The first electrode 710 of the organic light emitting diode 70 is formed on the planarization layer 180. That is, the organic light emitting diode (OLED) display 100 includes a plurality of the first electrodes 710 that are disposed for a plurality of pixels. At this time, a plurality of the first electrodes 710 are separated from each other. The first electrode 710 is connected to the drain electrode 177 through the electrode contact hole 182 of the planarization layer 180.

In addition, a pixel defining film 190 is on the planarization layer 180. The pixel defining film 190 has an opening that exposes the first electrode 710. That is, the pixel defining film 190 has a plurality of openings that are formed for each pixel. In addition, the first electrode 710 is disposed so as to correspond to the opening of the pixel defining film 190. However, the first electrode 710 is not necessarily disposed on only the pixel defining film 190, but a portion of the first electrode 710 may be disposed under the pixel defining film 190 so as to overlap the pixel defining film 190. The pixel defining film 190 may be made of resin such as polyacrylates resin and polyimides or silica-based inorganic materials.

An organic emission layer 720 is formed on the first electrode 710. The second electrode 730 is formed on the organic emission layer 720. As described above, the organic light emitting diode 70 includes the first electrode 710, organic emission layer 720 and the second electrode 730.

The organic emission layer 720 is formed of a low molecular weight organic material or a high molecular weight organic material. In addition, the organic emission layer 720 may be formed of a multilayer that includes the emission layer, hole injection layer (HIL), hole transport layer (HTL), electron transport layer (ETL) and electron injection layer (EIL). In the case of when all of them are included, the hole injection layer (HIL) is disposed on the first electrode 710 that is the anode, the hole transport layer (HTL), emission layer, electron transport layer (ETL), electron injection layer (EIL) are sequentially layered thereon.

The first electrode 710 and the second electrode 730 may be formed of a transparent conductive material, respectively, or semitransparent or reflective conductive material. According to the kind of the material that forms the first electrode 710 and the second electrode 730, the organic light emitting diode (OLED) display 100 may be a front surface light emitting type, a rear surface light emitting type or both surface light emitting type.

The encapsulation substrate 210 faces the display substrate 110. The encapsulation substrate 210 is a substrate that encapsulates at least the display area (DA) in the display substrate 110 in which the organic light emitting element is formed. In the case of when it is a front surface light emitting type or both surface light emitting type, the substrate 210 is formed of a transparent material such as glass or plastic. In the case of when it is a rear surface light emitting type, it is formed of an opaque material such as metal. This encapsulation substrate 210 has a plate shape, although the invention is not limited thereto.

The soft sealant 350 is disposed along the edge of the display substrate 110 and the encapsulation substrate 210. The soft sealant 350 adheres the display substrate 110 and the encapsulation substrate 210 and seals them. The soft sealant 350 is separated from the edge of the adherence surface of the display substrate 110 and the encapsulation substrate 210 at a predetermined interval and forms a line shape.

While not limited thereto, examples of the soft sealant 350 include any one that is selected from epoxy, acrylate, urethaneacrylate, cyanoacrylate. The soft sealant 350 is coated on the display substrate 110 in a liquid form and ultraviolet (UV) cured, heat cured or naturally cured. The soft sealant 350 that includes epoxy, acrylate, and urethaneacrylate is ultraviolet (UV) cured, the soft sealant 350 that includes acrylate is heat cured at the temperature that is less than 80° C., and the soft sealant 350 that includes cyanoacrylate is naturally cured.

Conventionally, since the display substrate 110 and the encapsulation substrate 210 are adhered by using the brittle sealant 360, in the case of when the display substrate 110 and the encapsulation substrate 210 are separated from each other because of external impact or deformation thereof, a stress concentration phenomenon occurs at the attachment surface of the brittle sealant 360 and the display substrate 110 and encapsulation substrate 210, and cracks occur from the attachment surface because of a characteristic of easy brittleness of the brittle sealant 360, such that it is diffused to the entire display substrate 110. The organic light emitting diode display does not generate cracks on the attachment surface of the soft sealant 350 and display substrate 110 and encapsulation substrate 210 because the soft sealant 350 has a high fracture toughness even though a stress concentration phenomenon occurs on the attachment surface of the soft sealant 350, the display substrate 110 and encapsulation substrate. Therefore, it is possible to prevent the display substrate 110 and encapsulation substrate 210 from being easily broken because of the external impact or deformation thereof.

The brittle sealant 360 and the soft sealant 350 are separated from each other at a predetermined interval, and disposed along the side of the display substrate 110 and the side of the encapsulation substrate 210, and fills a space between the display substrate 110 and the encapsulation substrate 210. Therefore, in order to prevent external moisture from permeating the display area (DA), the edge sides of the display substrate 110 and the encapsulation substrate 210 are encapsulated.

While not limited thereto, the soft sealant 350 and the brittle sealant 360 maintain the interval of 0.3 mm to 0.4 mm, and an air layer is formed between the soft sealant 350 and the brittle sealant 360. Accordingly, when the brittle sealant 360 is cured, it is possible to prevent the soft sealant 350 from being melted by generated heat, and it is possible to prevent outgassing in advance by melting of the soft sealant 350.

This brittle sealant 360 includes a frit material. While not limited thereto, the frit material may be formed of the frit material that includes fine glass particles. The fine glass particle includes one or more of magnesium oxide (MgO), calcium oxide (CaO), barium oxide (BaO), lithium oxide (Li₂O), sodium oxide (Na2O), potassium oxide (K₂O), boron oxide (B₂O₃), vanadium oxide (V₂O₅), zinc oxide (ZnO), tellurium oxide (TeO₂), aluminum oxide (Al₂O₃), silicon dioxide (SiO₂), lead oxide (PbO), tin oxide (SnO), phosphorous oxide (P₂O₅), ruthenium oxide (Ru₂O), rubidium oxide (Rb₂O), rhodium oxide (Rh₂O), ferrite oxide (Fe₂O₃), copper oxide (CuO), titanium oxide (TiO₂), tungsten oxide (WO₃), bismuth oxide (Bi₂O₃), antimony oxide (Sb₂O₃), (lead-borate glass), tin-phosphate glass, vanadate glass and borosilicate. The size of the fine glass particle is in the range of about 2 to 30 μm, more preferably about 5 μm to about 10 μm, but the invention is not limited thereto.

This brittle sealant 360 may reinforce the sealing of a portion in which coherence is weakened between the display substrate 110 and encapsulation substrate 210 by the soft sealant 350.

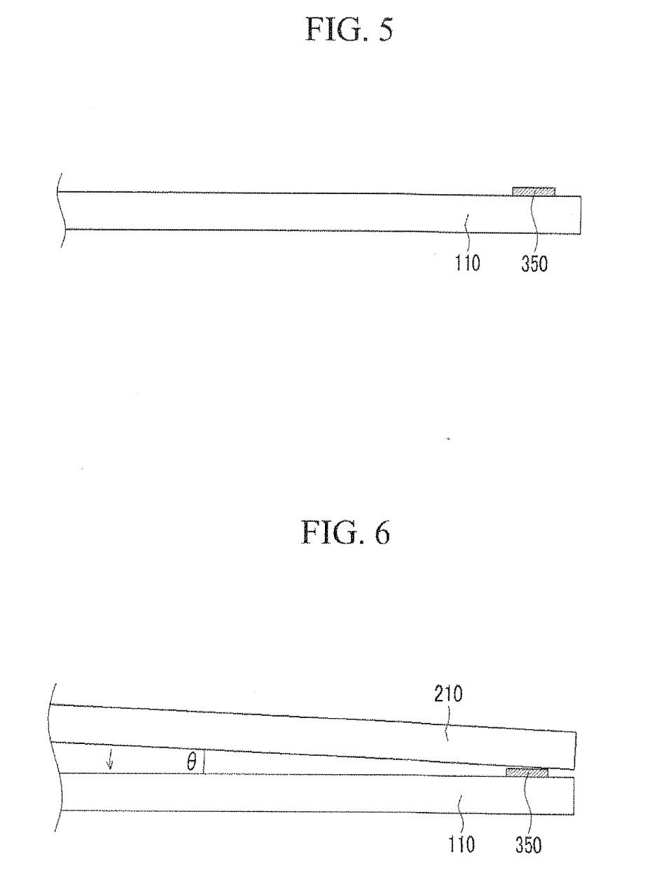

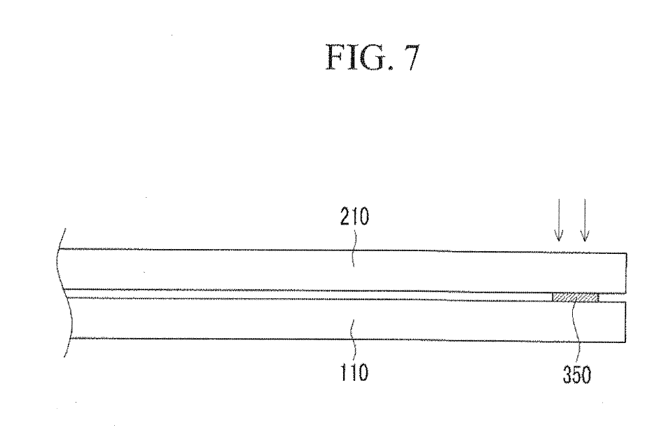

The manufacturing method of the organic light emitting diode (OLED) display that is shown in FIG. 1 to FIG. 4 will be described in detail referring to FIG. 5 to FIG. 7. FIG. 5 is a view that illustrates a step for forming the soft sealant 350 on the display substrate 110 in the manufacturing method of the organic light emitting diode (OLED) display according to an exemplary embodiment, FIG. 6 is a view that illustrates a step for pressing a portion of the encapsulation substrate 210 in the manufacturing method of the organic light emitting diode (OLED) display according to an exemplary embodiment, and FIG. 7 is a view that illustrates a step for curing the soft sealant 350 in the manufacturing method of the organic light emitting diode (OLED) display according to an exemplary embodiment.

As shown in FIG. 5, the soft sealant 350 is formed around the display substrate 110. The soft sealant 350 is coated in a line form at a position that is separated from the edge of the display substrate 110 in a display area (DA) direction.

As shown in FIG. 6, the encapsulation substrate 210 is contacted to a portion of the soft sealant 350 so that the horizontal surface of the encapsulation substrate 210 forms a coherence angle (θ), or in other words, an adhesion angle (θ), to the horizontal surface of the display substrate 110 to form an inclination state.

As shown in FIG. 7, a pressure is applied to a portion of the encapsulation substrate 210, such that the horizontal surface of the encapsulation substrate 210 is parallel to the horizontal surface of the display substrate 110. In addition, the soft sealant 350 adheres the display substrate 110 and the encapsulation substrate 210 by ultraviolet (UV) curing, heat curing or naturally curing them.

As described above, by applying the pressure to the soft sealant 350 to perform plastic deformation of the soft sealant 350, such that the display substrate 110 and the encapsulation substrate 210 are adhered with each other, the display substrate 110 and the encapsulation substrate 210 are strongly adhered. Therefore, even though the display substrate 110 and the encapsulation substrate 210 are separated by the external impact, the display substrate 110 and the encapsulation substrate 210 may be separated from each other while cracks do not occur on the attachment surface of the soft sealant 350, display substrate 110 and encapsulation substrate 210 until the maximum coherence angle (θ).

Next, as shown in FIG. 2, after the display substrate 110 and the encapsulation substrate 210 are adhered together, a brittle sealant 360 that connects the side of the display substrate 110 and the side of the encapsulation substrate 210 is formed. The brittle sealant 360 fills a space between the display substrate 110 and the encapsulation substrate 210. In addition, the brittle sealant 360 is melted by irradiating the laser or infrared rays. Thereafter, the melted brittle sealant 360 is cured while discharging moisture or organic binder, thus encapsulating the display substrate 110 and the encapsulation substrate 210.

Although a few embodiments of the present invention have been shown and described, it would be appreciated by those skilled in the art that changes may be made in this embodiment without departing from the principles and spirit of the invention, the scope of which is defined in the claims and their equivalents.

1-6. (canceled)

7. A method for manufacturing an organic light emitting diode (OLED) display, the method comprising:
forming a soft sealant around a display substrate;
contacting a horizontal surface of an encapsulation substrate with a portion of the soft sealant at an adhesion angle relative to a horizontal surface of the display substrate;
applying pressure to a portion of the encapsulation substrate so that the horizontal surface of the encapsulation substrate is parallel to the horizontal surface of the display substrate and so that the display substrate and the encapsulation substrate adhere to each other.

8. The method for manufacturing an organic light emitting diode (OLED) display of claim 7, further comprising forming a brittle sealant that connects a side of the display substrate and a side of the encapsulation substrate to each other after the display substrate and the encapsulation substrate are adhered to each other.

9. The method for manufacturing an organic light emitting diode (OLED) display of claim 8, wherein the brittle sealant fills a space between the display substrate and the encapsulation substrate.

10-20. (canceled)
